(19) United States
(12) Patent Application Publication
(10) Pub. No.: US 2018/0212084 A1
(43) Pub. Date: Jul. 26, 2018

(54) POROUS SILICON NANOWIRE PHOTOVOLTAIC CELL

(71) Applicant: UNITED ARAB EMIRATES UNIVERSITY, Al Ain (AE)

(72) Inventor: ADEL NAJAR, AL AIN (AE)

(21) Appl. No.: 15/417,210

(22) Filed: Jan. 26, 2017

(51) Int. Cl. H01L 31/0352; H01L 31/068; H01L 31/0224; H01L 31/0236; H01L 31/02

(52) U.S. Cl. CPC H01L 31/035227; H01L 31/068; H01L 31/02008; H01L 31/022475; H01L 31/02363; H01L 31/022425

(57) ABSTRACT

The porous silicon nanowire photovoltaic cell includes a first electrode, a p-type silicon layer, and a second electrode, which is formed from a transparent electrode with at least one metal contact. An array of porous silicon nanowires is sandwiched between the second electrode and the p-type silicon layer. Each of the porous silicon nanowires is formed from a porous n-type silicon core coated with a layer of p-type silicon. Empty spaces between the porous silicon nanowires of the array may be filled with indium tin oxide, thus forming a photoactive region formed from the array of porous silicon nanowires embedded in indium tin oxide. An up-conversion layer is sandwiched between the first electrode and the p-type silicon layer. Any suitable type of up-conversion material may be used for the up-conversion layer, such as NaYF₄:Er—Yb or the like. Alternatively, the up-conversion layer may be replaced by a down-conversion layer.

### BACKGROUND OF THE INVENTION

### 1. Field of the Invention

The present invention relates to photovoltaics, and particularly to a porous silicon nanowire photovoltaic cell using an array of porous silicon nanowires as a p-n junction, as well as an additional up-conversion layer.

### 2. Description of the Related Art

Photovoltaic devices typically employ a planar thin-film structure in which a negatively doped (n-type) material is stacked on top of a positively doped (p-type) material, or a positively doped (p-type) material is stacked on top of a negatively doped (n-type) material. In these planar photovoltaic devices, the light absorbing layer needs to be thick enough to effectively absorb impinging photons with energies larger than the bandgap energy of the light absorbing material. However, when the light absorbing layer in a planar structure is made thicker, this compromises the effective collection of the photo-generated carriers as the thickness of the light absorbing layer may be larger than the diffusion length of the minority carriers. Thus, the design of typical planar photovoltaic devices leads to a compromise between the thickness of the light absorbing layer for efficient light absorption and the effectiveness of carrier collection, thereby imposing limits on the efficiencies of these devices. As an example, a typical thin-film GaAs solar cell requires a light absorbing layer several microns thick to effectively absorb photons with energies higher than its bandgap energy, but as the diffusion length of the minority carriers is typically only a few hundred nanometers, many of the photo-generated carriers cannot be collected.

Rather than using planar p-n junctions in photovoltaic devices, radial p-n junctions are presently under investigation. In these structures, a long central n-type core extends out of a substrate and a p-type shell is wrapped around the core. In alternative configurations, the core is of a p-type material, while the shell is formed of an n-type material. Examples of such materials under investigation include nanowires formed from a GaAs core surrounded by an AlGaAs shell, as well as ZnO nanowires used in organic dye-based photovoltaic cells. Using such structures, one of the two photo-generated carrier types is collected in the shell orthogonally to the light absorption along the length of the core. Unlike in planar p-n junctions, increasing the length of the core to improve light absorption does not increase the distance the carriers need to travel before being collected, and therefore does not lead to the trade-off in light absorption and carrier collection found in typical planar devices.

Recent developments in the fabrication of nanowires extending out of substrates have made it possible to manufacture radial p-n junction photovoltaic devices. However, the efficiencies that have been achieved with these radial p-n junctions have been substantially less than corresponding planar devices, typically achieving solar cell efficiencies of less than 10%. It would be desirable to be able to fabricate a nanowire-based photovoltaic cell with efficiencies similar to, or surpassing, those of planar silicon photovoltaic cells.

Thus, a porous silicon nanowire photovoltaic cell solving the aforementioned problems is desired.

### SUMMARY OF THE INVENTION

The porous silicon nanowire photovoltaic cell includes a photoactive layer including porous silicon nanowires and an up-conversion layer. The porous silicon nanowire photovoltaic cell includes a first electrode, which may be formed from any suitable type of metal or the like, a p-type silicon layer, and a second electrode, which is formed from a transparent electrode with at least one metal contact. Similar to the first electrode, the at least one metal contact may be formed from any suitable type of metal, such as gold or the like, as in a conventional photovoltaic cell. The transparent electrode may be formed from any suitable type of conductive glass or the like, such as indium tin oxide (ITO), for example.

An array of porous silicon nanowires is sandwiched between the second electrode and the p-type silicon layer. Each of the porous silicon nanowires is formed from a porous n-type silicon core coated with a layer of p-type silicon. Empty spaces between the porous silicon nanowires of the array may be filled with ITO, for example, thus forming a photoactive region formed from the array of porous silicon nanowires embedded in ITO or the like.

An up-conversion layer is sandwiched between the first electrode and the p-type silicon layer. The up-conversion layer converts low-energy photons, which are reflected from the first electrode, into higher-energy photons, which can then be absorbed by the photoactive region, contributing to the overall photocurrent. Any suitable type of up-conversion material may be used for the up-conversion layer, such as NaYF₄:Er—Yb or the like.

In an alternative embodiment, the up-conversion layer is replaced by a down-conversion layer. In this embodiment, the porous silicon nanowire photovoltaic cell includes a first electrode, which may be formed from any suitable type of metal or the like, a p-type silicon layer, and a second electrode formed from a transparent electrode and at least one metal contact, as in the previous embodiment. Further, similar to the previous embodiment, a photoactive layer is formed from an array of porous silicon nanowires embedded in indium tin oxide. Each porous silicon nanowire is formed from a porous n-type silicon core coated with a layer of p-type silicon. The down-conversion layer is sandwiched between the second electrode and the photoactive layer, and the photoactive layer is sandwiched between the p-type silicon layer and the down-conversion layer. Any suitable type of down-conversion material may be used for the down-conversion layer, such as LiGdF₄:Eu³⁺ or the like.

These and other features of the present invention will become readily apparent upon further review of the following specification and drawings.

### BRIEF DESCRIPTION OF THE DRAWINGS

FIG. 1 is a side view in section of a porous silicon nanowire photovoltaic cell according to the present invention.

FIG. 2 is a side view in section of an alternative embodiment of the porous silicon nanowire photovoltaic cell.

Similar reference characters denote corresponding features consistently throughout the attached drawings.

### DETAILED DESCRIPTION OF THE PREFERRED EMBODIMENTS

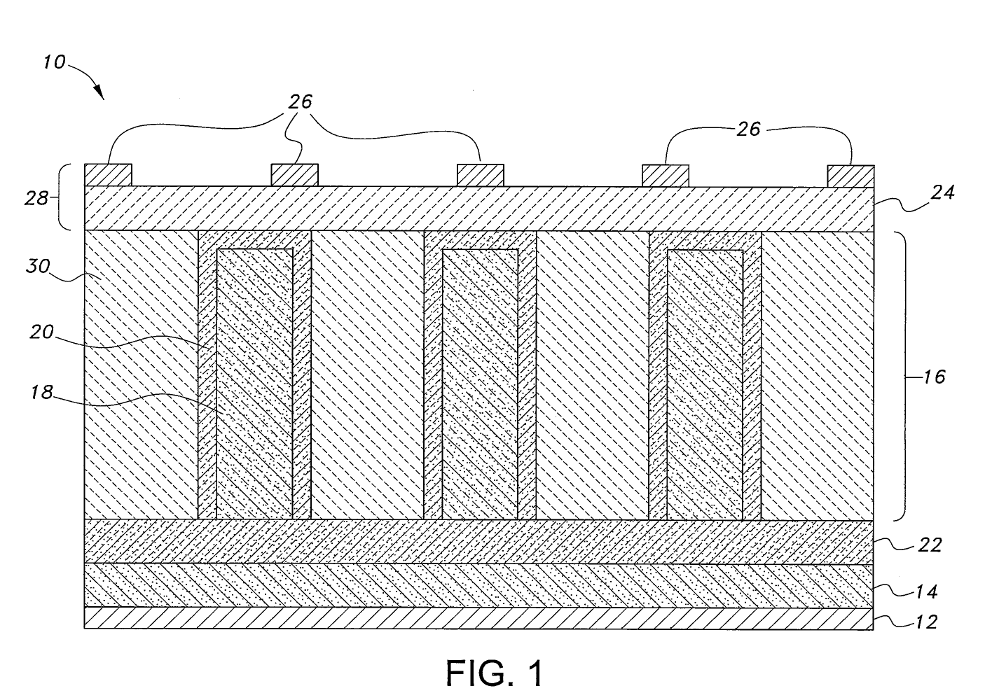

The porous silicon nanowire photovoltaic cell 10 includes a photoactive layer formed from porous silicon nanowires and an additional up-conversion layer. Similar to a conventional photovoltaic cell, as shown in FIG. 1, the porous silicon nanowire photovoltaic cell 10 includes a first electrode 12, which may be formed from any suitable type of metal or the like, a p-type silicon layer 22, and a second electrode 28, which is formed from a transparent electrode 24 with at least one metal contact 26. Similar to the first electrode 12, the at least one metal contact 26 may be formed from any suitable type of metal, such as gold or the like, as in a conventional photovoltaic cell. The transparent electrode 24 may be formed from any suitable type of conductive glass or the like, such as indium tin oxide (ITO), for example.

An array of porous silicon nanowires 16 is sandwiched between the second electrode 28 and the p-type silicon layer 22. Each of the porous silicon nanowires 16 is formed from a porous n-type silicon core 18 coated with a layer of p-type silicon 20. Empty spaces between the porous silicon nanowires of the array 16 may be filled with ITO 30, for example, thus forming a photoactive region formed from the array of porous silicon nanowires 16 embedded in ITO 30 or the like. As shown in FIG. 1, the porous silicon nanowires 16 are preferably vertically aligned and substantially parallel with respect to one another. It should be understood that the photoactive region, either with the additional ITO 30 or without the additional material, acts as a p-n junction, similar to that of a conventional photovoltaic cell. The photoactive region may alternatively be formed from luminescent quantum dots or metal nanoparticles, either alone or embedded in the ITO. The porous silicon nanowires 16 may be formed by any suitable process, such as metal assisted chemical etching (MacEtch) or the like. Alternatively, the porous silicon nanowires 16 may be formed, for example, by combining electrical anodization (i.e., for the formation of the porous silicon) followed by a metal electrodeless etching method (to form the nanowires), particularly of the type used for low resistivity silicon wafers.

An up-conversion layer 14 is sandwiched between the first electrode 12 and the p-type silicon layer 22. The up-conversion layer 14 converts low-energy photons, which are reflected from the first electrode 12, into higher-energy photons, which can then be absorbed by the photoactive region, contributing to the overall photocurrent. Any suitable type of up-conversion material may be used for the up-conversion layer 14, such as NaYF₄:Er—Yb or the like. Typically, NaYF₄:Er—Yb is particular to improving performance in the infrared region of solar radiation, thus it should be understood that the material used to form up-conversion layer 14 may be varied dependent upon the particular frequency band(s) of interest. Examples of other materials which may be used as the up-conversion material include NaYF₄:Yb—Tm, NaYF₄:Yb—HO, NaYF₄:Yb—Er—Nd, NaYF₄:Er, YF₃:Er, CaF₂:E₄, Y₂O₃:Er, BaC₁₂:Er, as well as NaYF₄-based core-shell nanoparticles and NaGdF₄-based core-shell nanoparticles as host materials doped or co-doped with NaYF₄:Er—Yb or core-shell-shell nanocrystals.

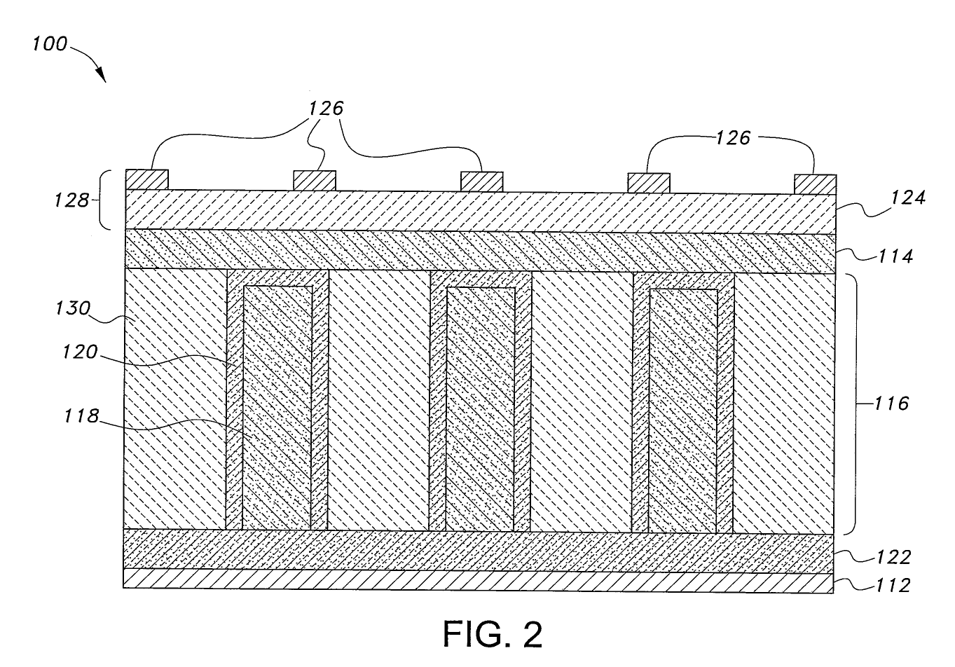

In the alternative embodiment of FIG. 2, the up-conversion layer 14 of porous silicon nanowire photovoltaic cell 10 is replaced by a down-conversion layer 114 in the alternative porous silicon nanowire photovoltaic cell 100. In this embodiment, porous silicon nanowire photovoltaic cell 100 includes a first electrode 112, which may be formed from any suitable type of metal or the like, a p-type silicon layer 122, and a second electrode 128 formed from a transparent electrode 124 and at least one metal contact 126, as in the previous embodiment. Further, similar to the previous embodiment, a photoactive layer is formed from an array of porous silicon nanowires 116 embedded in indium tin oxide 130. Each porous silicon nanowire 116 is formed from a porous n-type silicon core 118 coated with a layer of p-type silicon 120. The down-conversion layer 114 is sandwiched between the second electrode 128 and the array of porous silicon nanowires 116 forming the photoactive layer, and the photoactive layer is sandwiched between the p-type silicon layer 122 and the down-conversion layer 114. Any suitable type of down-conversion material may be used for the down-conversion layer 114, such as LiGdF₄:Eu³⁺ or the like. As in the previous embodiment, the photoactive region may alternatively be formed from luminescent quantum dots or metal nanoparticles, either alone or embedded in the ITO 130.

It is to be understood that the present invention is not limited to the embodiments described above, but encompasses any and all embodiments within the scope of the following claims.

1. A porous silicon nanowire photovoltaic cell, consisting of:
a first electrode;
a p-type silicon layer;
an up-conversion layer sandwiched between the first electrode and the p-type silicon layer;
a second electrode comprising a transparent electrode and at least one metal contact; and
a photoactive region, the photoactive region consisting of:
i) a vertical array of porous silicon nanowires sandwiched between the second electrode and the p-type silicon layer, wherein each of the porous silicon nanowires consists of a porous n-type silicon core directly coated with a layer of p-type silicon; and
ii) indium tin oxide completely filling the spaces between the porous silicon nanowires of the array of porous silicon nanowires, wherein the indium tin oxide filler extends from the second electrode to the p-type silicon layer thereby embedding the nanowires therein.

2. The porous silicon nanowire photovoltaic cell as recited in claim 1, wherein the up-conversion layer is selected from the group consisting of NaYF₄:Er—Yb, NaYF₄:Yb—Tm, NaYF₄:Yb—HO, NaYF₄:Yb—Er—Nd, NaYF₄:Er, YF₃:Er, CaF₂:E₄, Y₂O₃:Er, BaC₁₂:Er, NaYF₄ core-shell nanoparticles, and NaGdF₄ core-shell nanoparticles.

3. The porous silicon nanowire photovoltaic cell as recited in claim 1, wherein the transparent electrode is formed from a material selected from the group consisting of indium tin oxide, luminescent quantum dots, metal nanoparticles and combinations thereof.

4-7. (canceled)

8. A porous silicon nanowire photovoltaic cell, comprising:
a first electrode;
a p-type silicon layer;
a second electrode comprising a transparent electrode and at least one metal contact;
a photoactive layer comprising an array of porous silicon nanowires embedded in indium tin oxide, wherein each said porous silicon nanowire comprises a porous n-type silicon core coated with a layer of p-type silicon; and
a down-conversion layer sandwiched between the second electrode and the photoactive layer, the photoactive layer being sandwiched between the p-type silicon layer and the down-conversion layer.

9. The porous silicon nanowire photovoltaic cell as recited in claim 8, wherein the down-conversion layer comprises LiGdF₄:Eu³⁺.

10. The porous silicon nanowire photovoltaic cell as recited in claim 8, wherein the transparent electrode is formed from a material selected from the group consisting of indium tin oxide, luminescent quantum dots, metal nanoparticles and combinations thereof.
